(19) United States
(12) Patent Application Publication
(10) Pub. No.: US 2026/0270154 A1
(43) Pub. Date: Sep. 10, 2026

(54) Methods and Systems for Deploying Networks

(71) Applicant: Super Micro Computer, Inc., San Jose, CA (US)

(72) Inventors: Jun Xu, Cupertino, CA (US); Sung-Kuang Chung, Pleasanton, CA (US)

(21) Appl. No.: 19/075,643

(22) Filed: Mar. 10, 2025

(51) Int. Cl. H04L 41/14; G06F 30/18; H04L 41/0677

(52) U.S. Cl. CPC H04L 41/145; G06F 30/18; H04L 41/0677

(57) ABSTRACT

This application is directed to network deployment. A computer system obtains a network design file including information of a network, and the network includes network devices coupled to one another using virtual connections in the network design file. The computer system extracts, from the network design file, information of the virtual connections including a source port label of a source device and a destination port label of a destination device corresponding to each virtual connection. The computer system collects cable information of one or more cables that are connected in the network deployed based on the network design file, determines that each cable corresponds to a respective virtual connection in the network design file, compares the cable information of each of the one or more cables and information of the respective virtual connection extracted from the network design file, and automatically presents network deployment information of the network.

### TECHNICAL FIELD

This application relates generally to network technology including, but not limited to, methods, systems, and non-transitory computer-readable storage media for deploying a computer network, e.g., associated with a data center.

### BACKGROUND

A data center network is a complex system that connects servers, storage devices, and networking equipment to facilitate efficient data transmission and communication. It is deployed by physically connecting cables, such as fiber optics and Ethernet, between switches, routers, and servers to establish reliable connections. Technicians and engineers must carefully plan cable routes to optimize performance, minimize interference, and maintain proper airflow within the facility. However, manual cable deployment presents several challenges, including the risk of human error, inefficient use of time, and difficulties in scaling as data centers grow. Poor cable management can lead to tangled or misrouted connections, accidental disconnections, and increased troubleshooting time. Additionally, improper labeling or documentation can complicate maintenance and future upgrades, making manual deployment an inefficient and error-prone approach for large-scale data center networks.

### SUMMARY

In accordance with some embodiments of this application disclosed herein is at least the realization that many existing network deployment approaches separate network design, deployment, and operation from one another and rely on manual deployment of a data center network, which does not allow cable build-out or transceiver insertion issues to be tracked in real time during deployment. Various embodiments of this application are directed to methods and systems for deploying a computer network with real-time feedback information indicating a deployment status and whether there is any mistake with cable connections. Some implementations are applied in graphics processing unit (GPU) cluster deployment or large data center deployment. In some situations, information of network cable connections is collected and presented as an active topology for management of a large scale data center or an artificial intelligence (AI) cluster network during a network operation phase. In some embodiments, information of network connections is collected and presented during a network cable build-out phase, and applied to compare and validate whether network cable connections follow an associated network design. In an example, more than a thousand cables and transceivers are deployed for a GPU cluster (e.g., including 1024 GPUs). Each cable is required to follow a predefined virtual connection of the network design. Particularly, in some embodiments, cable connections are monitored in real time during network deployment with reference to the network design, thereby making sure that network design, deployment, and operation of the GPU cluster or the data center are consistent with one another.

In some embodiments, each of a transceiver insertion issue, a cable connection malfunction, a missing cable connection, and an erroneous cable connection into a wrong port is identified within a second during network deployment. In some embodiments, a network design is confirmed or adaptively adjusted based on a cable build-out. By these means, real-time feedback is made available with reference to a network design, and enables expedited system delivery, correct system network buildout, and high system performance during deployment of large networks and GPU clusters; so may computer networks be deployed quickly, efficiently, and with high fidelity, providing a confidence in a data center system build-out.

In one aspect, some implementations include a method for network deployment. The method is implemented at a computer system including one or more processors and memory. The method includes obtaining a network design file including network information of a network, and the network includes a plurality of network devices coupled to one another using a plurality of virtual connections in the network design file. The method further includes extracting, from the network design file, information of the plurality of virtual connections including a source port label of a source device and a destination port label of a destination device corresponding to each virtual connection. The method further includes collecting cable information of a set of one or more cables that are connected in the network deployed based on the network design file, determining that each of the set of one or more cables corresponds to a respective virtual connection of the network in the network design file, comparing the cable information of each of the set of one or more cables and information of the respective virtual connection extracted from the network design file, and automatically presenting network deployment information of the network that is deployed. In some embodiments, the network deployment information of the network includes one or more of: a deployment status and an error status of the set of one or more cables.

In some embodiments, the set of one or more cables including a first cable, the method further includes, based on a comparison result, determining that the first cable has a connection error. Presenting the network deployment information of the network includes generating a message indicating the connection error of the first cable. Further, in some embodiments, the message includes an inquiry regarding whether to override the connection error, and the method further includes, in response to a user confirmation, modifying the network design file (e.g., the source port label and the destination port label corresponding to the first cable) based on the connection error of the first cable.

In some embodiments, the method further includes executing a network deployment application on a client device, rendering a graphical user interface (GUI), and visualizing, on the GUI, the network design file. Visualizing the network design file further includes displaying a plurality of first affordance items representing the plurality of network devices and a plurality of second affordance items representing the plurality of virtual connections.

In some embodiments, the information of the plurality of virtual connections applied in the network includes one or more of: a rack identification of the source device, a device label of the source device, a port identification of the source port, a rack identification of the destination device, a device label of the destination device, a port identification of the destination port, a cable type, a cable length, a source label of a respective cable, a destination label of the respective cable associated with each virtual connection.

In another aspect, some implementations include a computer system. The computer system includes one or more processors and memory having instructions stored thereon, which when executed by the one or more processors cause the processors to perform any of the above methods.

In another aspect, some implementations include a non-transitory computer-readable storage medium, having instructions stored thereon, which when executed by one or more processors of a computer system cause the processors to perform any of the above methods.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a front view of an example server rack that supports one or more servers, in accordance with some embodiments.

FIG. 2 is a block diagram of an example system module in a typical computer device, which may be applied as a server in FIG. 1, in accordance with some embodiments.

FIG. 3A is a network diagram of an example computer network having two switching layers, in accordance with some embodiments.

FIG. 3B is a network diagram of an example computer network having top-of-rack (ToR) switching, in accordance with some embodiments.

FIG. 4 is a flow diagram of an example process for deploying a network with real time feedback, in accordance with some embodiments.

FIG. 5 is a flow diagram of another example process for deploying a network, in accordance with some embodiments.

FIG. 6 is an example network deployment environment having a network deployment server communicatively coupled to one or more client devices, in accordance with some embodiments.

FIG. 7 is a block diagram of an example computer system (e.g., a network deployment server, a client device, or a combination thereof), in accordance with some embodiments.

FIG. 8 is a flow diagram of an example method for managing network deployment, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details.

Various embodiments of this application are directed to methods and systems for deploying a computer network with at least real-time feedback information indicating a deployment status and whether there is any mistake with cable connections. Some implementations are applied in GPU cluster deployment or large data center deployment. Information of network connections may be monitored during a network deployment phase, and applied to compare and validate whether network cable connections follow virtual connections of the network design in real time while cables are being connected to enable the computer network. Each cable used in a GPU cluster or a data center is required to follow a predefined virtual connection of an associated network design. Cable connections are monitored in real time during network deployment with reference to the network design, thereby making sure that network design, deployment, and operation of the GPU cluster or the data center are consistent with one another. In some embodiments, each of a transceiver insertion issue, a cable connection malfunction, a missing cable connection, and an erroneous cable connection into a wrong port is identified within a second during network deployment. By these means, real-time feedback is made available with reference to a network design, and enables expedited system delivery, correct system network buildout, and high system performance during deployment of large networks and GPU clusters.

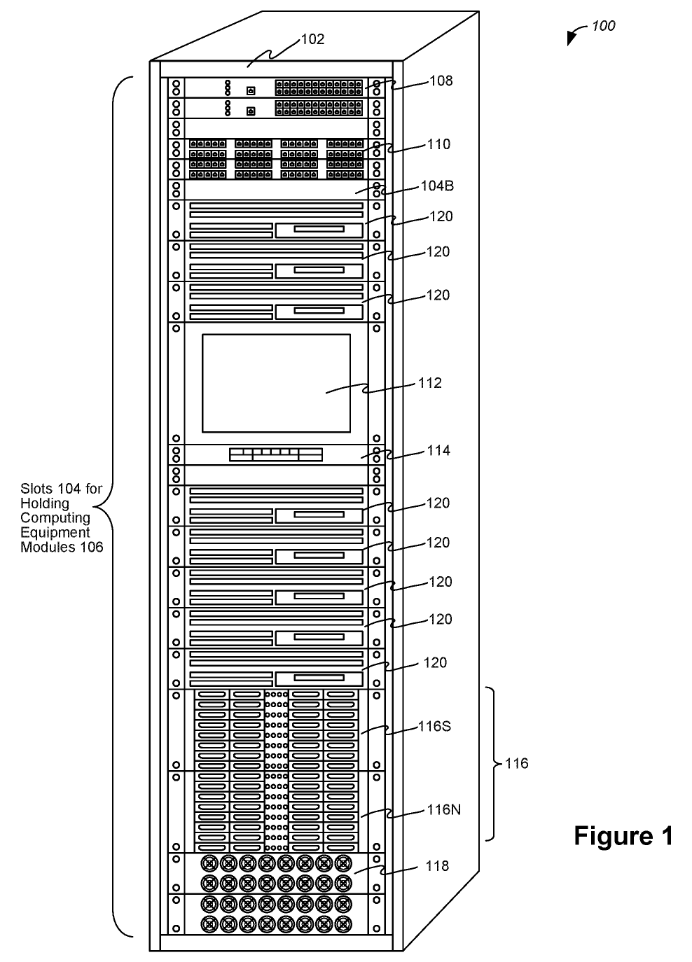

FIG. 1 is a front view of an example server rack 100 (also known as a rack mount, a rack cabinet, or simply a rack) that supports one or more servers 120, in accordance with some embodiments. The server rack 100 includes a frame 102 and a plurality of slots 104, and may be used in a data center, a server room, or a network closet for supporting, organizing, and managing a plurality of computing equipment modules 106 (e.g., servers 120, storage devices 116S and 116N, networking equipment, and other types of hardware). Each of the plurality of slots 104 of the server rack 100 is configured to receive and support a respective computing equipment module 106. In some embodiments, the plurality of slots 104 include at least one blank slot 104B that is not used to provide mechanical support to any equipment module 106 and can receive an equipment module 106 if needed. In some implementations, the server rack 100 has a predefined width of 19 or 23 inches, a height up to 84 inches or more, and a depth selected from 24, 32, 40, or 48 inches. A rack unit (1U) is a standard size for a server 120 and other equipment modules 106 that are installed in the server rack 100. The server rack 100 offers room for the server 120 and other equipment modules 106, which are 19 inch wide and have heights (e.g., 1U, 2U, 4U), expressed in rack units.

Examples of the computing equipment modules 106 supported by the plurality of slots 104 of the server rack 100 include, but are not limited to, a firewall module 108, a switch box 110, a server 120, a display device 112, a keyboard 114, a solid-state drive (SSD) 116S, a network-attached storage 116N, and an uninterruptible power supply (UPS) 118. Each computing equipment module 106 plays a respective role in maintaining a network and computing environment. In some embodiments, a firewall module 108 is a network security device that monitors and controls incoming and outgoing network traffic based on predetermined security rules, thereby establishing a barrier between a trusted internal network and untrusted external networks. The firewall module 108 may be placed near a network ingress point to protect the server rack 100 from unauthorized access, malware, and cyberattacks. In some embodiments, the firewall module 108 includes packet filtering, stateful inspection, VPN support, and intrusion prevention systems (IPS). In some embodiments, a switch box 110 is placed near the network ingress point jointly with the firewall module 108, and configured to receive incoming signals and forward the incoming signals (e.g., which may be converted to electrical signals) to different servers 120 mounted on the server rack 100. The switch box 110 is applied in the server rack 100 to minimize cable length and ensure efficient network traffic management. The switch box 110 may support different speeds (e.g., 800 gigabits per second (Gbps), 1.6 Tbs, 3.2 Tbs), have multiple ports (24, 48, etc.), and offer features like virtual local area network (VLAN) support, PoE (Power over Ethernet), and managed or unmanaged capabilities.

The plurality of computing equipment modules 106 of the server rack 100 may include a plurality of servers 120 each of which is configured to provides data, resources, services, or programs to other client devices over one or more wired or wireless communication networks. Each server 120 is mounted in a slot 104 of the server rack 100 and configured to provide one or more services (e.g., web hosting, database management, and application support). The servers 120, mounted on the server rack 100, may provide higher processing power, large memory capacity, redundant power supplies, and hot-swappable components for high availability and reliability compared with individual client devices. In some embodiments, the one or more rack servers 120 include a plurality of graphics processing units (GPU) configured to implement machine learning operations, e.g., in a data center associated with machine learning tasks. In some embodiments, the server 120 includes one or more processors, memory storing one or more programs for execution by the one or more processors, and a system housing for enclosing the one or more processors, the memory, and a power supply component.

The SSD 116S and the network-attached storage 116N are configured to provide storage space for the servers 120 installed in the server rack 100. The SSD uses flash memory to store data and shows high speed, low latency, durability, and lower power consumption, and diverse capacities and form factors compared to hard drive devices (HDDs). Conversely, the network-attached storage (NAS) 116N is a dedicated file storage device that provides data access to a network and allows a large number of different types of client devices to retrieve data from centralized disk capacity. In some embodiments, the network-attached storage 116N may have a high capacity, redundant array of independent disks (RAID), support for a plurality of file-sharing protocols (NFS, SMB/CIFS, FTP), user management, and backup features. In some embodiments, the SSDs 116S are storage drives for speed, and for example, used within the servers 120 disposed on the same server rack 100, while the NAS 116N is configured for file sharing, data backup, and remote access.

In some implementations, the UPS 118 is applied to provide emergency power to other computing equipment modules 106 in case of a power outage, allowing them to remain operational long enough to safely shut down or switch to an alternative power source. In an example, the UPS 118 is mounted in the server rack 100 or placed on a bottom slot to support the weight, providing backup power to other computing equipment modules 106. The UPS 118 provides one or more of battery backup, surge protection, voltage regulation, real-time monitoring, management software, and/or varying runtimes based on capacity and load.

The server rack 100 further includes a plurality of mechanical structures configured to provide mechanical support, or facilitate access, to the plurality of computing equipment modules 106. The plurality of mechanical structures include one or more of: an open frame rack (e.g., having no door or side panel), mounting rails, cable management features (e.g., arms, hooks, and trays), power strips, shelves, drawers, and blanking panels. In some embodiments, the plurality of mechanical structures also includes a rack enclosure (e.g., cabinet), lockable doors, and side panels to protect the computing equipment modules 106 from unauthorized access. In an example, the server rack 100 includes, or is coupled to, a plurality of panels configured to convert the server rack 100 to a server cabinet. In some embodiments, the server rack 100 further includes a cooling system or a ventilation system to facilitate heat dissipation. Using a server rack 100 helps optimize space, improve cooling efficiency, simplify maintenance, and enhance the overall organization and management of information technology (IT) infrastructure.

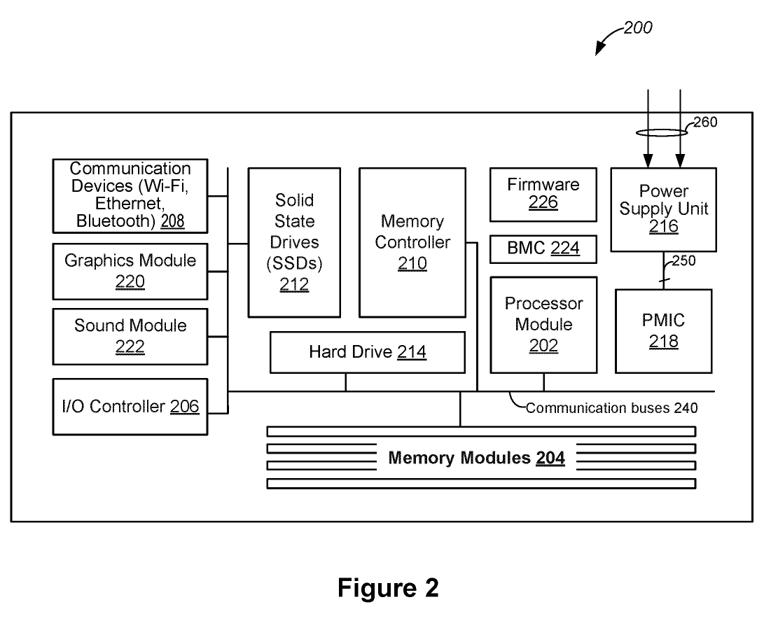

FIG. 2 is a block diagram of an example system module 200 in a typical electronic device, which may be applied as a server 120 in FIG. 1, in accordance with some embodiments. The system module 200 in this electronic device includes at least a processor module 202, memory modules 204 for storing programs, instructions and data, an input/output (I/O) controller 206, one or more communication interfaces such as communication devices 208, and one or more communication buses 240 for interconnecting these components. In some embodiments, the I/O controller 206 allows the processor module 202 to communicate with an I/O device (e.g., a keyboard, a mouse or a track-pad) via a universal serial bus interface. In some embodiments, the communication devices 208 include one or more interfaces (e.g., for Wi-Fi, Ethernet, and Bluetooth networks) each allowing the electronic device to exchange data with another external source, e.g., a server or another electronic device. In some embodiments, the communication buses 240 include circuitry (sometimes called a chipset) that interconnects and controls communications among various system components included in the system module 200.

In some embodiments, the processor module 202 includes one or more central processing units (CPU). In some embodiments, the processor module 202 includes one or more graphics processing units (GPUs), a digital signal processor (DSP), a field-programmable gate array (FPGA), an application-specific integrated circuit (ASIC), a tensor processing unit (TPU), a microcontroller (MCU), a neural processing unit (NPU), or a combination thereof. In some embodiments, the system module 200 further includes a baseboard management controller (BMC) 224 disposed on a motherboard and for remote management (e.g., IPMI, Redfish standard). The BMC 224 is configured to provide an interface to allow administrators to monitor, troubleshoot, and update the server 120 without physical access. In some embodiments, the system module 200 further includes BIOS/UEFI firmware 226 (e.g., contained on the motherboard) configured to initialize and test hardware components during startup and provide an interface to configure hardware settings.

More specifically, in some embodiments, a communication device 208 applied in a server 120 is configured to manage, route, or facilitate network traffic, enabling communication within a network or the Internet. Examples of the communication device 208 include, but are not limited to an NIC (e.g., an Ethernet or Wi-Fi adapter), a network switch, a network router, a load balancer, a firewall, a wireless access point (WAP) device, a modem, a repeater node, a network hub, a network bridge, a gateway, an intrusion detection and prevention systems, and a virtual private network (VPN) appliance. In some embodiments, a subset of communication devices 208 are configured to exchange data with another external source for the one or more CPUs. Alternatively and additionally, in some embodiments, a subset of communication devices 208 are configured to exchange data with external sources for non-CPU processors (e.g., GPUs). In some implementations, a plurality of communication devices 208 are applied in a network infrastructure of the server 120, e.g., in a data center or enterprise environment.

In some embodiments, the memory modules 204 include high-speed random-access memory, such as DRAM, static random-access memory (SRAM), double data rate (DDR) dynamic random-access memory (RAM), or other random-access solid state memory devices. In some embodiments, the memory modules 204 include non-volatile memory, such as one or more magnetic disk storage devices, optical disk storage devices, flash memory devices, or other non-volatile solid state storage devices. In some embodiments, the memory modules 204, or alternatively the non-volatile memory device(s) within the memory modules 204, include a non-transitory computer readable storage medium. In some embodiments, memory slots are reserved on the system module 200 for receiving the memory modules 204. Once inserted into the memory slots, the memory modules 204 are integrated into the system module 200.

In some embodiments, the system module 200 further includes one or more components selected from a memory controller 210, solid state drives (SSDs) 212, a hard disk drive (HDD) 214, a power supply unit (PSU) 216, power management integrated circuit (PMIC) 218, a graphics module 220, and a sound module 222. The memory controller 210 is configured to control communication between the processor module 202 and memory components, including the memory modules 204, in the electronic device. The SSDs 212 are configured to apply integrated circuit assemblies to store data in the electronic device, and in many embodiments, are based on NAND or NOR memory configurations. The HDD 214 is a conventional data storage device used for storing and retrieving digital information based on electromechanical magnetic disks. The PSU 216 is configured to receive a plurality of power supply signals 260 and provide a plurality of DC power supplies 250 (e.g., 12V, 54V). The PMIC 218 is configured to modulate the plurality of DC power supplies 250 to other desired DC voltage levels, e.g., 5V, 3.3V or 1.8V, as required by various components or circuits (e.g., the processor module 202) within the electronic device. The graphics module 220 is configured to generate a feed of output images to one or more display devices according to their desirable image/video formats. The sound module 222 is configured to facilitate the input and output of audio signals to and from the electronic device under control of computer programs.

It is noted that communication buses 240 also interconnect and control communications among various system components including components 210-224.

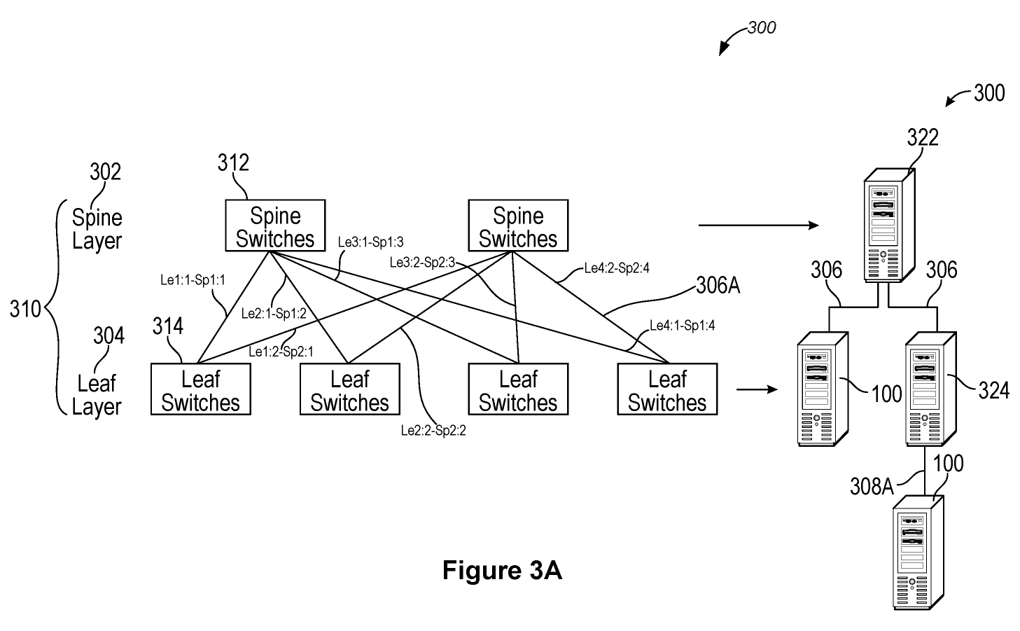

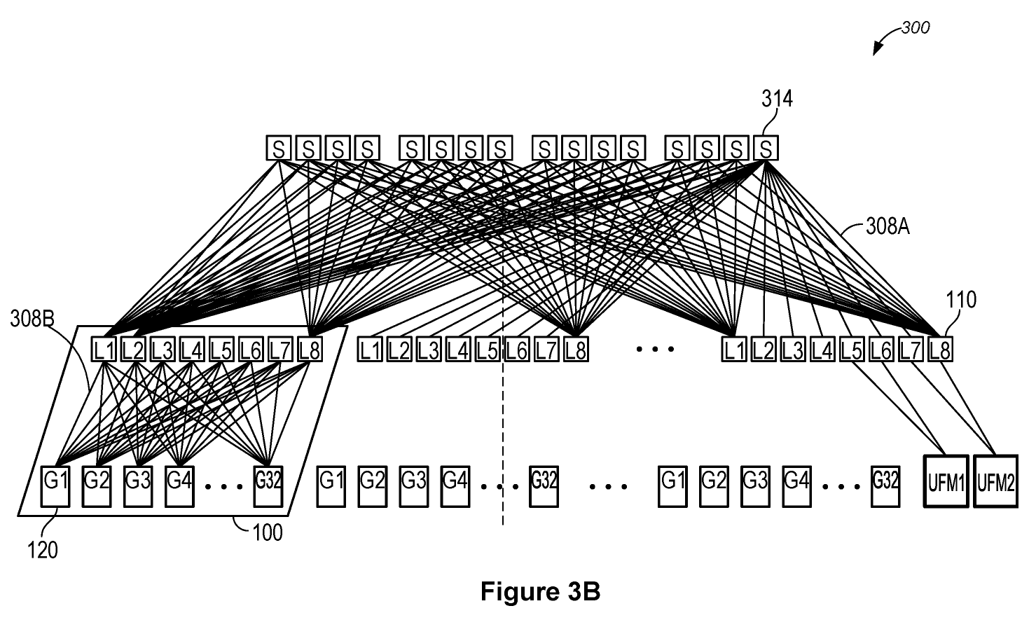

FIG. 3A is a network diagram of an example computer network 300 having a spine layer 302 and a leaf layer 304, in accordance with some embodiments. FIG. 3B is a network diagram of another example computer network 300 having top-of-rack (ToR) switching, in accordance with some embodiments. The computer network 300 is implemented in a spine-leaf architecture 310, which is a data center network topology including two switching layers, a spine layer 302 and a leaf layer 304. The spine-leaf architecture 310 is applied to reduce network latency and hop count and improve network efficiency of the computer network 300. The spine layer 302 includes a plurality of spine switches 312, and the leaf layer 304 includes a plurality of leaf switches 314. In some embodiments, the plurality of spine switches 312 may interconnect the plurality of leaf switches 314 in a mesh topology. Referring to FIG. 3B, the plurality of leaf switches 314 aggregate traffic from a plurality of servers 120 and are connected directly into the plurality of spine layer 302 or an associated network core. Stated another way, the plurality of leaf switches 314 connect to the plurality of spine switches 312 and mesh into the spine layer 302, forming an access layer that delivers network connection points for the plurality servers 120. In some embodiments, the plurality of leaf switches 114 are connected to both the plurality of servers 120 and a plurality of storage devices 116 (e.g., SSDs 116S, network-attached storage 116N). In some embodiments, the computer network 300 includes a plurality of server racks 100 each of which further includes a subset of respective servers 120. The computer network 300, implemented in the spine-leaf architecture 310, uses the spine layer 302 and the leaf layer 304 to create a two-layer topology. Connections may be made through the spine layer 302, enabling a single hop between leaves and minimizing latency and bottlenecks.

In some embodiments, a data center includes one or more network racks (e.g., a spine rack 322, a leaf rack 324) and a plurality of compute and storage racks 100. The plurality of spine switches 312 are mounted on one or more spine racks 322 separate from the plurality of compute and storage racks 100. Further, in some embodiments, the plurality of leaf switches 114 are mounted on the plurality of compute and storge racks 100. A set of leaf switches 314 connect directly to servers 120 and storage devices 116 in each compute and storage rack 100, and uplink to a set of spine switches 312 located on the one or more spine racks 322 for higher-level aggregation. The set of leave switches 314 are positioned at the top (e.g., for ToR switching) or middle to minimize cable lengths and improve cable management. The plurality of spine switches 312 and the plurality of leaf switches 314 are located on different racks 322 and 100, and coupled to one another across the different racks 322 and 100 via cables 306 (e.g., optical fiber cables, electrical cables). For example, a cable 306A is associated with a label “Le4:2:Sp2:4,” indicating that the cable 306 is connected between Port 2 of Leaf Switch 4 (e.g., a source port of a source device) and Port 4 of Spine Switch 2 (e.g., a destination port of a destination device). On each compute and storage rack 100, the set of leaf switches 314 are further coupled to associated servers 120 and storage devices 116 via cables (e.g., optical fiber cables, electrical cables).

Alternatively, in some embodiments, referring to FIG. 3B, the plurality of leaf switches 114 are mounted on one or more leaf racks 324 distinct from the one or more spine racks 322 and the plurality of compute and storage racks 100. A set of leaf switches 314 connect to switch box 110 and further to servers 120 and storage devices 116 located in each compute and storage rack 100 (e.g., server rack 100 in FIG. 1). The set of leaf switches 314 and the switch box 110 are located on different racks 324 and 100, and coupled to one another across the different racks 324 and 100 via cables 308A (e.g., optical fiber cables, electrical cables). On each compute and storage rack, the switch box 110 is further coupled to the associated servers 120 and storage devices 116 via cables 308B (e.g., optical fiber cables, electrical cables).

In some embodiments not shown, a computer network may be implemented in an architecture distinct from the spine-leave architecture. For example, the computer network is implemented in three tiers including a network core, an aggregation/distribution layer, and an access layer. The core layer interconnects data center aggregation modules while connecting to the network core. Access switches connect to servers 120 and storage devices 116 while the aggregation layer brings together access layer traffic and provides a redundant connection to the access layer. Cables are applied to couple the network core to the aggregation/distribution layer or couple the aggregation/distribution layer to the access layer.

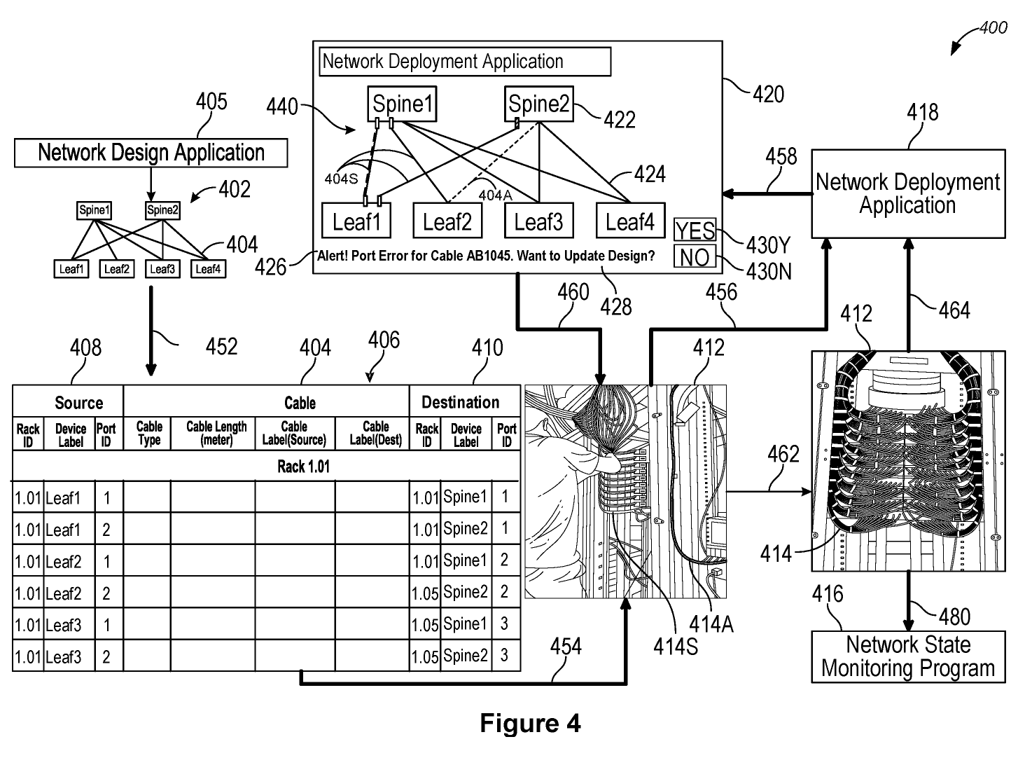

FIG. 4 is a flow diagram of an example process 400 for deploying a network 300 with real time feedback, in accordance with some embodiments. In some embodiments, a network design file 402 is created to include a hypothetic network topology using a network design application 405, such as Microsoft Visio, PowerPoint, or other graphic tools. The network design file 402 is static and includes network information of the network 300 (e.g., a data center network, a GPU cluster network) to be deployed. The network 300 includes a plurality of network devices (e.g., storage 116, servers 120, leaf switches 314, spine switches 312) coupled to one other with a plurality of virtual connections 404. The network design file 402 can map each port to port for the network virtual connections 404 directly or via a separate connection port mapping file 406. Stated another way, in some embodiments, the network design file 402 includes, or is associated with (operation 452) a connection port mapping file 406 that includes information of the plurality of virtual connections 404. In accordance with the connection port mapping file 406, each virtual connection 404 is coupled between a source port of a source device 408 and a destination port of a destination device 410. The network design file 402 or the connection port mapping file 406 is used (operation 454) by engineers to execute a cable build-out 412, e.g., in response to a design instruction. The cable build-out 412 includes a process to connect a plurality of cables 414 based on the plurality of virtual connections 404 and make the network 300 ready for use, thereby bringing (operation 462) a network deployment process 400 to a completed state. In some situation, the executed build-out 412 is consistent with the network design file 402 and the associated connection port mapping file 406 of the network 300. Conversely, in some situations, the executed cable build-out 412 deviates from the network design file 402 and/or the associated connection port mapping file 406 of the network 300.

In some embodiments, network deployment or cable build-out 412 includes cable labeling. The plurality of cables 414 are marked with identifiers to distinguish and manage the cables 414, thereby organizing the network 300 and facilitating maintenance, troubleshooting, and upgrades. In some embodiments, each cable 414 includes one or more cable labels for a cable type, a cable purpose, a source device 408, a source port, a destination device 410, a cable identifier, and data and installer information. For example, the cable type is one of a power cable, Ethernet (Cat5e, Cat6, etc.), fiber optic, or one or more other cable types. The cable labels may include a port number on a switch box 110, identifying wherein a respective cable 414 starts and ends. In some embodiments, the cable labels include an installation date and an engineer’s initial or name for historical tracking. In some embodiments, cable labeling follows a standardized format, such as the TIA/EIA-606 standard, which ensures consistency across different network setups. This practice minimizes confusion, reduces downtime, and enhances network reliability by making it easier to trace cables during maintenance or troubleshooting.

In some embodiments, after the network 300 is completely deployed (e.g., with the plurality of cables 414 connected), a network state monitoring program 416 is implemented (operation 480) to provide real-time status information of the network 300 by determining a network topology, provisioning the network 300, discovering a network device (e.g., storage 116, servers 120, leaf switches 314, spine switches 312), detecting cable or transceiver insertion, and notifying a fault, e.g., in real time while the network 300 is being deployed or functioning. Under some circumstances, the cable build-out 412 derivates from the network design file 402, and an engineer intervenes the network deployment process 400 to compare the cable build-out 412 with the network design file 402 and identify any mistake made during the process 400. When the network design file 402 includes thousands of virtual connections 404, it is a challenge for the engineer to accurately and promptly identify any mistake arising during network deployment. Additionally, in some embodiments, the network design file 402 is updated, and a subset or all of the plurality of cables of the network 300 is reconnected, e.g., with manual validation.

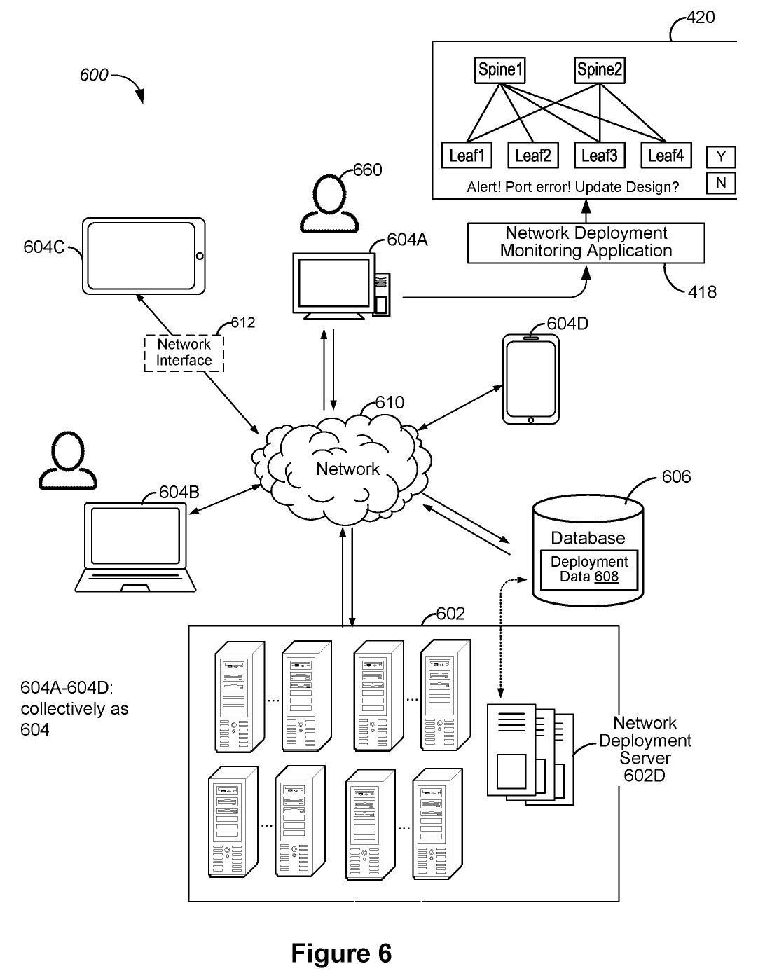

In some embodiments, while an engineer (e.g., engineer 660 in FIG. 6) is connecting the plurality of cables 414, cable information is collected (operation 456) in real time for a set of one or more cables 414S that have already been connected in the network 300. The cable information of each of the set of one or more cables that are being connected in the network may include one of: a cable identifier, a cable type, information of an incoming port, and information of an outgoing port. Each of the set of one or more cables 414S corresponds to a respective virtual connection 404S associated with the network design file 402. The cable information of each of the set of one or more cables 414S is compared to information of the respective virtual connection 404S extracted from the network design file 402. Network deployment information 440 of the network 300 is automatically presented (operation 458) based on a comparison result. The network deployment information of the network 300 may include one or more of: a deployment status (e.g., whether a particular cable is deployed or not) and an error status of the set of one or more cables 414S.

In some embodiments, the set of one or more cables 414S may include a single current cable 414S that is currently being connected by the engineer. Alternatively, in some embodiments, the set of one or more cables 414S may include two or more cables 414S that are less than all of the plurality of cables 414, but include the current cable that is currently being connected by the engineer. The connection error is detected in real time, while the plurality of cables 414 are being connected in the network 300 and before the plurality of cables 414 are completely connected. Alternatively, in some embodiments, the set of one or more cables 414S may include all of the plurality of cables 414. Conversely and additionally, in some embodiments, the connection error is detected in the set of one or more cables 414S (e.g., all or less than all of the cables 414S that are deployed), after the plurality of cables 414 are completely connected.

In some embodiments, a network deployment application 418 is executed on a client device (e.g., client device 604 in FIG. 6), and a graphical user interface (GUI) 420 is rendered on the client device. The network design file 402 is visualized on the GUI 420 to display a plurality of first affordance items 422 representing the plurality of network devices (e.g., storage 116, servers 120, leaf switches 314, spine switches 312) and a plurality of second affordance items 424 representing the plurality of virtual connections 404. In some embodiments, one of the plurality of first affordance items 422 is actionable. In some embodiments, one of the plurality of second affordance items 424 is actionable.

In some embodiments, the plurality of virtual connections 404 includes a subset of virtual connections 404S that have been deployed using the set of one or more cables 414S. The subset of virtual connections 404S corresponding to the set of one or more cables 414S is visually highlighted on the graphical user interface 420. For each of the set of one or more cables 414S, the source port of the source device 408, the destination port of the destination device 410, the virtual connection 404 itself or a combination thereof is visually highlighted based on a deployment status of the respective cable 414S (e.g., whether the cable 414S is connected to the source port, the destination port, or both).

In some embodiments, the set of one or more cables 414S includes a first cable 414A. Based on the comparison result, it is determined that the first cable 414A has a connection error. A message 426 is generated and displayed to indicate the connection error of the first cable 414A. Further, in some embodiments, the message 426 includes an inquiry 428 (e.g., “Want to update Design?”) regarding whether to override the connection error. Information items and/or affordance items may be displayed to guide (operation 460) the engineer during deployment until the cable build-out 412 is completed (operation 462). For example, two affordance items 430Y and 430N are displayed to allow the engineer to choose overriding or correcting the connection error. If the engineer provides a user action on the affordance item 430Y, which amounts to a user confirmation of overriding the connection error, the network design file 402 is modified based on the connection error of the first cable 414A. Conversely, if the engineer provides a user action on the affordance item 430N, which amounts to a user rejection of overriding the connection error, the network design file 402 is not modified, and the engineer needs to reconnect the first cable 414A to correct the connection error.

In some embodiments, after the cable information is collected (operation 456) for the set of one or more cables 414S that have already been connected, the cable information if further processed based on a network protocol to detect at least one of a network change, a cable change, and a transceiver change. For instance, the network protocol is one of: Simple Network Management Protocol (SNMP), Link Layer Discovery Protocol (LLDP), Cisco Discovery Protocol (CDP), and Border Gateway Protocol Link-State (BGP LS). In some embodiments, the message 426 is presented to notify the engineer of this network change in real time. In some situations, this network change corresponds to the connection error, and the engineer may choose to re-connect one or more cables 414 to correct the connection error. Alternatively, in some situations, this network change is applied to update the network design file 402 in response to a user selection of the affordance item 430Y.

In some embodiments, the network deployment application 418 determines that a first cable 414A has a connection error. The first cable 414A corresponds to a virtual connection 404A, and the virtual connection 404A is visually highlighted on the graphical user interface 420. For example, the virtual connection 404A is displayed in a distinct line color or a distinct line width. In another example, the virtual connection 404A is displayed with a flashing effect (e.g., visually blinks and rapidly changes color). Additionally, in some embodiments, the network deployment application 418 determining that the connection error of the first cable is associated with one of a plurality of components including: a source port of the source device 408, a destination port of the destination device 410, and the first cable 414A itself. The one of the plurality of components associated with the connection error of the first cable 414A is visually highlighted (e.g., with a distinct color, a distinct size, or a flashing effect) on the graphical user interface 420, helping the engineer identify any error with the first cable 414A accurately and promptly.

In some embodiments, after the network 300 is deployed and during network operations, the network deployment application 418 is applied (operation 464) to collect the network progress data (e.g., network topology data and network traffic data) to monitor network production operations. The network topology and associated network production operations may be modified, e.g., to enhance network performance of the network 300.

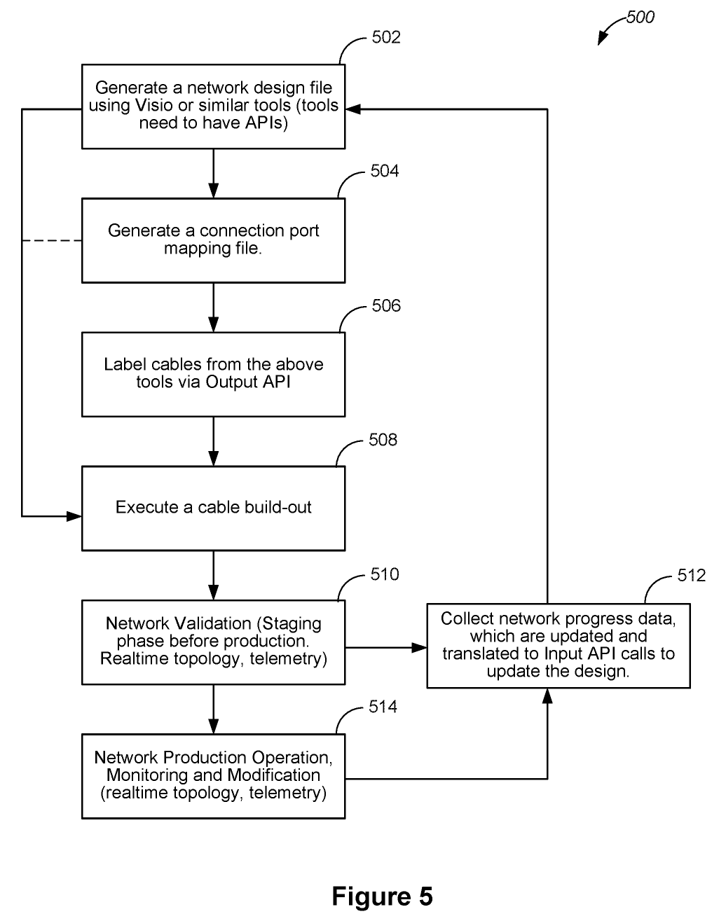

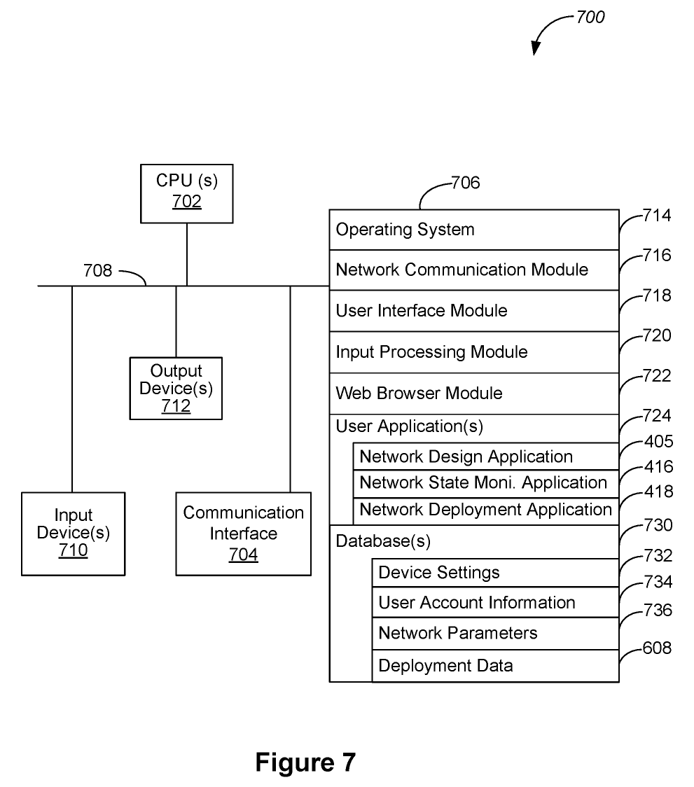

FIG. 5 is a flow diagram of another example process 500 for deploying a network 300, in accordance with some embodiments. The process 500 may be implemented by a computer system (e.g., computer system 700 in FIG. 7) including a network deployment server and a client device. The computer system creates (operation 502) a network design file 402 including a hypothetic network topology using a network design application 405, such as Microsoft Visio, PowerPoint, or other graphic tools. The network design file 402 includes, or is converted to (operation 504), a connection port mapping file 406 that further includes information of the plurality of virtual connections 404. In some embodiments, the information of the plurality of virtual connections 404 applied in the network 300 includes one or more of: a rack identification of the source device 408, a device label of the source device 408, a source port label of the source port on a source rack, a rack identification of the destination device 410, a device label of the destination device 410, a destination port label of the destination port on a destination rack, a cable type, a cable length, a source label of a respective cable 414, and a destination label of the respective cable 414 associated with each virtual connection 404.

In some embodiments, a network deployment application 418 is executed on a client device, and a graphical user interface (GUI) 420 is rendered on the client device. Further, in some embodiments, the network deployment application 418 includes a design Application Programming Interface (API) configured to facilitate communication with the network design application 405. The network design file 402 may be loaded via the design API, and visualized on the GUI 420 of the network deployment application 418. Alternatively, in some embodiments, the network deployment application 418 imports the network design file 402 from the network design application 405.

In some embodiments, the connection port mapping file 406 identifies the plurality of virtual connections 404 of the network design file 402, and the plurality of virtual connections 404 are implemented by a plurality of cables 414 during network deployment. The network deployment application 418 is configured to label (operation 506) the plurality of cables 414, e.g., using an output API. For example, the connection port mapping file 406 defines a cable type, a cable length, a source port of a source device 408, and a destination port of a destination device 410 for each cable 414. The network design file 402 or the connection port mapping file 406 is used (operation 508) by an engineer to execute a cable build-out 412, e.g., in response to a design instruction.

In some situations, while the engineer is deploying the network 300, the engineer connects the plurality of cables 414 successively based on the network design file 402 or the connection port mapping file 406. The network deployment application 418 validates (operation 510) the network 300 that is deployed during a network staging phase, in real time during deployment, and while the network 300 is operating after deployment. During network operation, network telemetry may collect network traffic data from network devices on the network 300 for further analysis. In some embodiments, during network deployment, the network deployment application 418 collects (operation 512) network progress data, which may indicate real-time transceiver and cable status. The network progress data are compared with the connection port mapping file 406 to determine whether one or more cables 414 have been deployed properly based on the connection port mapping file 406, thereby guiding the engineer to continue the cable build-out, until the network 300 is fully deployed according to the network design file 402 or the connection port mapping file 406.

During network deployment, if there is a connection error detected with a cable 414, the network deployment application 418 may present an alert, indicating that the cable is connected with an error. Further, in some embodiments, the network deployment application 418 receives an instruction of accepting the connect error and modify the network design file 402. The network progress data are collected (operation 512) and used to update the network design file 402 (e.g., using one or more API calls) to be consistent with the detected transceiver and cable status. More details on overriding the connector error are discussed above with reference to the user interface 420 of FIG. 4.

In some embodiments, after the network 300 is deployed and during network operations, the network deployment application 418 is applied to collect the network progress data (e.g., network topology data and network traffic data) to monitor (operation 514) network production operations. The network topology and associated network production operations may be modified, e.g., to enhance network performance of the network 300.

FIG. 6 is an example network deployment environment 600 having a network deployment server 602 communicatively coupled to one or more client devices 604, in accordance with some embodiments. The one or more client devices 604 may be, for example, desktop computers 604A, laptop computer 604B, tablet computers 604C, or mobile phones 604D. Each client device 604 can collect data or user inputs, executes user applications, and present outputs on its user interface. The collected data or user inputs can be processed locally at the client device 604 and/or remotely by the server(s) 602. The one or more servers 602 provide system data (e.g., boot files, operating system images, and user applications) to the client devices 604, and in some embodiments, process the data and user inputs received from the client device(s) 604 when the user applications are executed on the client devices 604. In some embodiments, the data processing environment 600 further includes a storage 606 for storing data related to the servers 602, client devices 604, and user applications executed thereon.

In various embodiments of this application, the one or more servers 602 include a network deployment server 602D configured to manage network deployment (e.g., collect cable information, identify deployment status, detect a deployment error, generate an alert message), before a network 300 is deployed, while a network 300 is being deployed, and after the network 300 has been fully deployed. The one or more servers 602 may further include a plurality of servers 120 (FIG. 1) for which a network 300 is deployed during a network deployment process. The network deployment process may be monitored in real time by the network deployment server 602D.

The one or more servers 602 are configured to enable real-time data communication with the client devices 604 that are remote from each other or from the one or more servers 602. Further, in some embodiments, the one or more servers 602 are configured to implement data processing tasks that cannot be or are preferably not completed locally by the client devices 604. For example, the network deployment server 602D may extract information of a plurality of virtual connections 404 from a network design file 402 and generate a separate connection port mapping file 406, allowing the plurality of virtual connections 404 to be visualized on the client device 104 associated with a network engineer 660 and facilitating network deployment by the network engineer. Stated another way, in some embodiments, the information of the plurality of virtual connections extracted from the network design file 402 is organized in a tabular format, and stored in the connection port mapping file 406 to be used as a reference during network deployment.

In some embodiments, the storage 606 stores deployment data 608 associated with a network deployment process of a network 300. The deployment data 608 include, but are not limited to, a subset or all of: the network design file 402, the connection port mapping file 406, cable information collected for a set of one or more cables 414S that are connected in the network, and network deployment information determined based on a comparison of the cable information and the information of the virtual connections 404.

The one or more servers 602, one or more client devices 604, and storage 606 are communicatively coupled to each other via one or more communication networks 610, which are the medium used to provide communications links between these devices and computers connected together within the data processing environment 600. The one or more communication networks 610 may include connections, such as wire, wireless communication links, or fiber optic cables. Examples of the one or more communication networks 610 include local area networks (LAN), wide area networks (WAN) such as the Internet, or a combination thereof. The one or more communication networks 610 are, optionally, implemented using any known network protocol, including various wired or wireless protocols, such as Ethernet, Universal Serial Bus (USB), FIREWIRE, Long Term Evolution (LTE), Global System for Mobile Communications (GSM), Enhanced Data GSM Environment (EDGE), code division multiple access (CDMA), time division multiple access (TDMA), Bluetooth, Wi-Fi, voice over Internet Protocol (VoIP), Wi-MAX, or any other suitable communication protocol. A connection to the one or more communication networks 610 may be established either directly (e.g., using 3G/4G connectivity to a wireless carrier), or through a network interface 612 (e.g., a router, switch, gateway, hub, or an intelligent, dedicated whole-home control node), or through any combination thereof. As such, the one or more communication networks 610 can represent the Internet of a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers, consisting of thousands of commercial, governmental, educational and other computer systems that route data and messages.

In some embodiments, the network deployment server 602D is communicatively coupled to the plurality of client devices 604 via one or more wireless communication networks 610, and configured to host a network deployment platform for the plurality of client devices 604 associated with a plurality of user accounts. Each client device 604 may be applied by the network engineer 660 to monitor and guide network deployment in real time via a respective user account. During network deployment, the network deployment application 418 is executed by the network deployment server 602D and an individual client device 604 jointly. For example, the plurality of user accounts of the network deployment application 418 includes a first user account associated with the client device 604B. While the network engineer 660 applies the client device 604B to guide network deployment, a user interface 420 is displayed to present real-time network deployment information 440 (FIG. 4). Further, in some situations, the user interface 420 is displayed to preview the network design file 402 before network deployment or review the cable information of the plurality of cables 414 after network deployment.

FIG. 7 is a block diagram of an example computer system 700 (e.g., a network deployment server 602D, a client device 604, or a combination thereof), in accordance with some embodiments. The computer system 700 includes a client device 604 associated with a network engineer 660, and the client device 604 is communicatively coupled to a network deployment server 602D via one or more wireless communication networks 610. The network deployment server 602 is configured to host a network deployment application 418 having a plurality of user accounts including a particular user account associated with a particular client device. Each client device 604 may execute a client-side network deployment application 418 for managing network deployment in real time and in an interactive manner.

The computer system 700, typically, includes one or more processing units (CPUs) 702, one or more communication interfaces 704, memory 706, and one or more communication buses 708 for interconnecting these components (sometimes called a chipset). The computer system 700 includes one or more input devices 710 that facilitate user input, such as a keyboard, a mouse, a voice-command input unit or microphone, a touch screen display, a touch-sensitive input pad, a gesture capturing camera, or other input buttons or controls. In some embodiments, the client device 604 includes one or more optical cameras (e.g., an RGB camera) for capturing images. The computer system 700 also includes one or more output devices 712 that enable presentation of user interfaces and display content, including one or more speakers and/or one or more visual displays.

Memory 706 includes high-speed random access memory, such as DRAM, SRAM, DDR RAM, or other random access solid state memory devices; and, optionally, includes non-volatile memory, such as one or more magnetic disk storage devices, one or more optical disk storage devices, one or more flash memory devices, or one or more other non-volatile solid state storage devices. Memory 706, optionally, includes one or more storage devices remotely located from one or more processing units 702. Memory 706, or alternatively the non-volatile memory within memory 706, includes a non-transitory computer readable storage medium. In some embodiments, memory 706, or the non-transitory computer readable storage medium of memory 706, stores the following programs, modules, and data structures, or a subset or superset thereof:

Operating system 714 including procedures for handling various basic system services and for performing hardware dependent tasks;

Network communication module 716 for connecting the network deployment server 602D or client device 604 to other devices (e.g., server 602, client device 604, or storage 606) via one or more communication interfaces 704 (wired or wireless) and one or more communication networks 610, such as the Internet, other wide area networks, local area networks, metropolitan area networks, and so on;

User interface module 718 for enabling presentation of information (e.g., a graphical user interface for application(s) 724, widgets, websites and web pages thereof, and/or games, audio and/or video content, text, etc.) at each client device 604 via one or more output devices 712 (e.g., displays, speakers, etc.);

Input processing module 720 for detecting one or more user inputs or interactions from one of the one or more input devices 710 and interpreting the detected input or interaction;

Web browser module 722 for navigating, requesting (e.g., via HTTP), and displaying websites and web pages thereof, including a web interface for logging into a user account associated with a client device 604 or another electronic device, controlling the client or electronic device if associated with the user account, and editing and reviewing settings and data that are associated with the user account;

One or more user applications 724 for execution by the computer system 700 (e.g., games, social network applications, smart home applications, and/or other web or non-web based applications), where in some embodiments, the user application(s) 724 includes one or more of a network design application 405, a network state monitoring application 416, and a network deployment application 418; and

One or more databases 730 for storing at least data including one or more of:

Device settings 732 including common device settings (e.g., service tier, device model, storage capacity, processing capabilities, communication capabilities, etc.) of the network deployment server 602D or client devices 604;

User account information 734 for the one or more user applications 724, e.g., user names, security questions, account history data, user preferences, and predefined account settings;

Network parameters 736 for the one or more communication networks 610, e.g., IP address, subnet mask, default gateway, DNS server and host name;

Deployment data 608 including, but not limited to, network design files 402, connection port mapping file 406, cable information collected for a set of one or more cables 414S that are connected in the network, and network deployment information determined based on a comparison of the cable information and the information of the virtual connections 404 for each user account associated with the network deployment application 418.

Optionally, the one or more databases 730 are stored in one of the network deployment server 602D, individual client devices 604, and storage 606 of the computer system 700. Optionally, the one or more databases 730 are distributed in more than one of the network deployment server 602D, individual client devices 604, and storage 606 of the computer system 700. In some embodiments, more than one copy of the above data is stored at distinct devices, e.g., two copies of a network design file 402 are stored at the network deployment server 602 and storage 606, respectively.

Each of the above identified elements may be stored in one or more of the previously mentioned memory devices, and corresponds to a set of instructions for performing a function described above. The above identified modules or programs (i.e., sets of instructions) need not be implemented as separate software programs, procedures, modules or data structures, and thus various subsets of these modules may be combined or otherwise re-arranged in various embodiments. In some embodiments, memory 706, optionally, stores a subset of the modules and data structures identified above. Furthermore, memory 706, optionally, stores additional modules and data structures not described above.

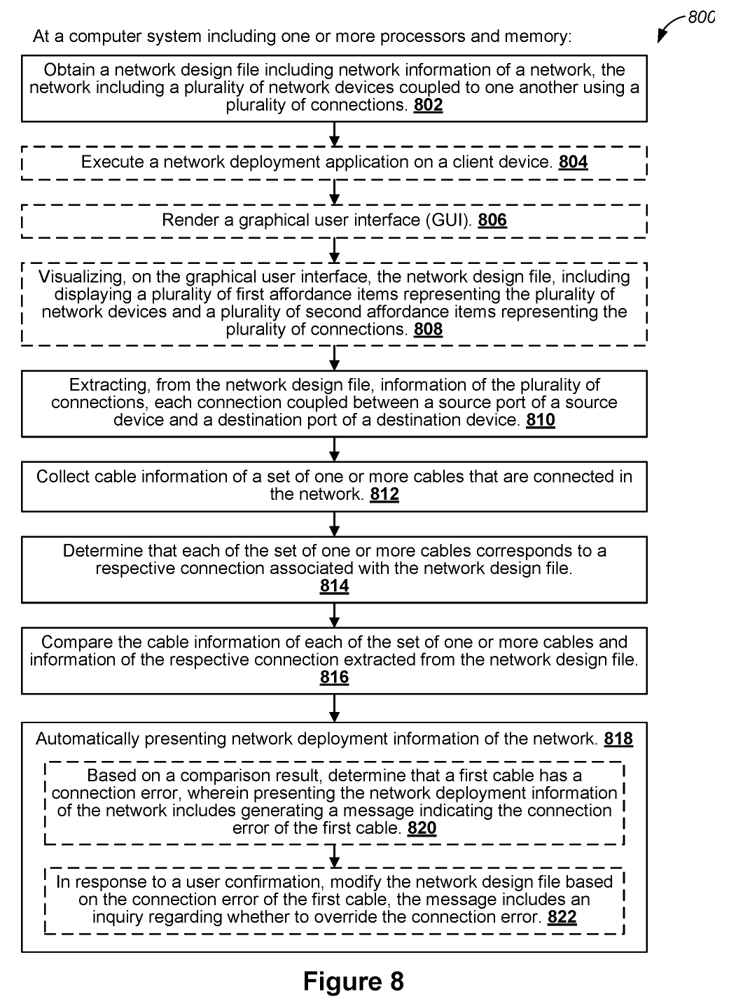

FIG. 8 is a flow diagram of an example method 800 for managing network deployment, in accordance with some embodiments. In some embodiments, the method 800 is governed by instructions that are stored in a non-transitory computer readable storage medium and are executed by one or more processors of a computer system 700 (e.g., a network deployment server 602D, a client device 604, or a combination thereof). Each of the operations shown in FIG. 8 may correspond to instructions stored in the computer memory or computer readable storage medium of a network deployment server 602D. The computer readable storage medium may include a magnetic or optical disk storage device, solid state storage devices such as flash memory, or other non-volatile memory device or devices. The computer readable instructions stored on the computer readable storage medium may include one or more of: source code, assembly language code, object code, or other instruction format that is interpreted by one or more processors. Some operations in the method 800 may be combined and/or the order of some operations may be changed.

The method 800 is implemented at the computer system 700 to set up a network 300 including a plurality of servers 120. The computer system 700 obtains (operation 802) a network design file 402 including network information of a network 300. The network 300 includes a plurality of network devices coupled to one another using a plurality of virtual connections 404 in the network design file 402. The computer system 700 extracts (operation 810), from the network design file 402, information of the plurality of virtual connections 404. Information of each virtual connection 404 includes a source port label of a source device 408 and a destination port label of a destination device 410. The computer system 700 collects (operation 812) cable information of a set of one or more cables 414S that are connected in the network 300 deployed based on the network design file 402, determines (operation 814) that each of the set of one or more cables 414S corresponds to a respective virtual connection 404 in the network design file 402, and compares (operation 816) the cable information of each of the set of one or more cables 414S and information of the respective virtual connection 404 extracted from the network design file 402. The computer system 700 automatically presents (operation 818) network deployment information 440 of the network 300 that is deployed. In some embodiments, the network deployment information 440 of the network 300 includes one or more of: a deployment status and an error status of the set of one or more cables 414S.

In some embodiments, the set of one or more cables 414S includes a first cable 414A (FIG. 4). Based on a comparison result, the computer system 700 determines (operation 820) that the first cable 414A has a connection error, and generates a message 426 (FIG. 4) indicating the connection error of the first cable 414A. Further, in some embodiments, the message includes an inquiry regarding whether to override the connection error. In response to a user confirmation, the computer system 700 modifies (operation 822) the network design file 402 based on the connection error of the first cable 414A.

In some embodiments, the computer system 700 executes (operation 804) a network deployment application 418 on a client device 604, renders (operation 806) a graphical user interface 420 (GUI), and visualizes (operation 808) the network design file 402 on the graphical user interface 420. A plurality of first affordance items 422 are displayed on the GUI 420 representing the plurality of network devices and a plurality of second affordance items 424 representing the plurality of virtual connections 404. Further, in some embodiments, the plurality of virtual connections 404 includes a subset of virtual connections 404S that have been deployed using the set of one or more cables 414S. The computer system 700 visually highlights the subset of virtual connections 404S corresponding to the set of one or more cables 414S on the graphical user interface 420. In some embodiments, the computer system 700 determines that a first cable 414A has a connection error and visually highlights the respective virtual connection 404A corresponding to the first cable 414A on the graphical user interface 420. In some embodiments, the computer system 700 determines that a first cable 414A has a connection error, determines that the connection error of the first cable 414A is associated with one of a plurality of components including a source port of the source device 408, a destination port of the destination device 410, and the first cable 414A. The computer system 700 visually highlights the one of the plurality of components associated with the connection error of the first cable 414A on the graphical user interface 420.

In some embodiments (FIG. 4), the information of the plurality of virtual connections 404 applied in the network 300 includes one or more of: a rack identification of the source device, a device label of the source device, a port identification of the source port, a rack identification of the destination device, a device label of the destination device, a port identification of the destination port, a cable type, a cable length, a source label of a respective cable 414, and a destination label of the respective cable 414 associated with each virtual connection 404.

In some embodiments, the plurality of virtual connections 404 correspond to a plurality of cables 414, and the set of one or more cables 414S include less than all of the plurality of cables 414. The computer system 700 determines that the set of one or more cables 414S has a connection error, in real time while the plurality of cables 414 are being connected in the network 300 and before the plurality of cables 414 are completely connected.

In some embodiments, the plurality of virtual connections 404 correspond to a plurality of cables 414. The computer system 700 determines that the set of one or more cables 414S has a connection error, after the plurality of cables 414 are completely connected.

In some embodiments, the computer system 700 includes a client device 604 associated with a network engineer 660, and the client device 604 is communicatively coupled to a network deployment server 602D via one or more wireless communication networks 610. The network deployment server 602D is configured to host a network deployment application 418 (FIG. 4) having a plurality of user accounts including a first user account associated with the client device 604.

In some embodiments, the computer system 700 processes the cable information based on a network protocol to detect at least one of a network change, a cable change, and a transceiver change. Further, in some embodiments, the network protocol is one of: simple network management protocol (SNMP), link layer discovery protocol (LLDP), CISCO discovery protocol (CDP), and border gateway protocol link-state (BGP LS).

In some embodiments, the cable information of each of the set of one or more cables 414S that are being connected in the network 300 includes one of: a cable identifier, a cable type, information of an incoming port (also called a source port), and information of an outgoing port (also called a destination port). Each of the plurality of network devices includes a switch (e.g., switch 312 or 314, switch box 110), a server 120, and a router.

In some embodiments, the network deployment information 440 is tracked and presented in real time in a network deployment application 418 (FIG. 4). The computer system 700 obtains a network design file 402 by importing the network design file 402 from a network design application 405 (FIG. 4) distinct from the network deployment information 440.

In some embodiments, the computer system 700 organizes the information of the plurality of virtual connections 404 in a tabular format (FIG. 4), and stores the information of the plurality of virtual connections 404 in a separate connection port mapping file 406 configured to be used as a reference during network deployment.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. Implementations of the above-described techniques may include hardware, a method or process, or computer software on a computer-accessible medium. Other embodiments of this aspect include corresponding computer systems, apparatus, and computer programs recorded on one or more computer storage devices, each configured to perform the actions of the methods described above.

It should be understood that the particular order in which the operations in FIG. 8 have been described are merely exemplary and are not intended to indicate that the described order is the only order in which the operations could be performed. One of ordinary skill in the art would recognize various ways to deploy a network of a data center as described herein. Additionally, it should be noted that details of other processes described herein with respect to other figures(e.g., FIGS. 1-7) are also applicable in an analogous manner to method 800 described above with respect to FIG. 8. For brevity, these details are not repeated here.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A method for network deployment, comprising:
at a computer system including one or more processors and memory:
obtaining a network design file including network information of a network, the network including a plurality of network devices coupled to one another using a plurality of virtual connections in the network design file;
extracting, from the network design file, information of the plurality of virtual connections including a source port label of a source device and a destination port label of a destination device corresponding to each virtual connection;
collecting cable information of a set of one or more cables that are connected in the network deployed based on the network design file;
determining that each of the set of one or more cables corresponds to a respective virtual connection in the network design file;
comparing the cable information of each of the set of one or more cables and information of the respective virtual connection extracted from the network design file; and
automatically presenting network deployment information of the network that is deployed.

2. The method of claim 1, wherein the network deployment information of the network includes one or more of: a deployment status and an error status of the set of one or more cables.

3. The method of claim 1, the set of one or more cables including a first cable, the method further comprising:
based on a comparison result, determining that the first cable has a connection error, wherein presenting the network deployment information of the network includes generating a message indicating the connection error of the first cable.

4. The method of claim 3, wherein the message includes an inquiry regarding whether to override the connection error, the method further comprising:
in response to a user confirmation, modifying the network design file based on the connection error of the first cable.

5. The method of claim 1, further comprising:
executing a network deployment application on a client device;
rendering a graphical user interface (GUI); and
visualizing, on the graphical user interface, the network design file, including displaying a plurality of first affordance items representing the plurality of network devices and a plurality of second affordance items representing the plurality of virtual connections.

6. The method of claim 5, wherein the plurality of virtual connections includes a subset of virtual connections that have been deployed using the set of one or more cables, the method further comprising:
visually highlighting the subset of virtual connections corresponding to the set of one or more cables on the graphical user interface.

7. The method of claim 5, further comprising:
determining that a first cable has a connection error; and
visually highlighting the respective virtual connection corresponding to the first cable on the graphical user interface.

8. The method of claim 5, further comprising:
determining that a first cable has a connection error;
determining that the connection error of the first cable is associated with one of a plurality of components including: a source port of the source device, a destination port of the destination device, and the first cable; and
visually highlighting the one of the plurality of components associated with the connection error of the first cable on the graphical user interface.

9. The method of claim 1, wherein the information of the plurality of virtual connections applied in the network includes one or more of: a rack identification of the source device, a device label of the source device, a port identification of the source port, a rack identification of the destination device, a device label of the destination device, a port identification of the destination port, a cable type, a cable length, a source label of a respective cable, and a destination label of the respective cable associated with each virtual connection.

10. The method of claim 1, wherein the plurality of virtual connections correspond to a plurality of cables, and the set of one or more cables include less than all of the plurality of cables, the method further comprising:
determining that the set of one or more cables has a connection error, in real time while the plurality of cables are being connected in the network and before the plurality of cables are completely connected.

11. A computer system, comprising:
one or more processors; and
memory having instructions stored thereon, which when executed by the one or more processors cause the processors to perform operations for:
obtaining a network design file including network information of a network, the network including a plurality of network devices coupled to one another using a plurality of virtual connections in the network design file;
extracting, from the network design file, information of the plurality of virtual connections including a source port label of a source device and a destination port label of a destination device corresponding to each virtual connection;
collecting cable information of a set of one or more cables that are connected in the network deployed based on the network design file;
determining that each of the set of one or more cables corresponds to a respective virtual connection in the network design file;
comparing the cable information of each of the set of one or more cables and information of the respective virtual connection extracted from the network design file; and
automatically presenting network deployment information of the network that is deployed.

12. The computer system of claim 11, wherein the plurality of virtual connections correspond to a plurality of cables, the method further comprising:
determining that the set of one or more cables has a connection error, after the plurality of cables are completely connected.

13. The computer system of claim 14, wherein the computer system includes a client device associated with a network engineer, and the client device is communicatively coupled to a network deployment server via one or more wireless communication networks, and wherein the network deployment server is configured to host a network deployment application having a plurality of user accounts including a first user account associated with the client device.

14. The computer system of claim 11, wherein the instructions further cause the processors to perform operations for:
processing the cable information based on a network protocol to detect at least one of a network change, a cable change, and a transceiver change.

15. The computer system of claim 14, wherein the network protocol is one of:
Simple Network Management Protocol (SNMP);
Link Layer Discovery Protocol (LLDP);
Cisco Discovery Protocol (CDP); and
Border Gateway Protocol Link-State (BGP LS).

16. A non-transitory computer-readable storage medium, having instructions stored thereon, which when executed by one or more processors of a computer system cause the processors to perform operations for:
obtaining a network design file including network information of a network, the network including a plurality of network devices coupled to one another using a plurality of virtual connections in the network design file;
extracting, from the network design file, information of the plurality of virtual connections including a source port label of a source device and a destination port label of a destination device corresponding to each virtual connection;
collecting cable information of a set of one or more cables that are connected in the network deployed based on the network design file;
determining that each of the set of one or more cables corresponds to a respective virtual connection in the network design file;
comparing the cable information of each of the set of one or more cables and information of the respective virtual connection extracted from the network design file; and
automatically presenting network deployment information of the network that is deployed.

17. The non-transitory computer-readable storage medium of claim 16, wherein the cable information of each of the set of one or more cables that are being connected in the network includes one of: a cable identifier, a cable type, information of an incoming port, and information of an outgoing port.

18. The non-transitory computer-readable storage medium of claim 16, wherein each of the plurality of network devices includes a switch, a server, and a router.

19. The non-transitory computer-readable storage medium of claim 16, wherein the network deployment information is tracked and presented in real time in a network deployment application, and obtaining a network design file further comprises:
importing the network design file from a network design application distinct from the network deployment information.

20. The non-transitory computer-readable storage medium of claim 16, wherein the instructions further cause the processors to perform operations for:
organizing the information of the plurality of virtual connections in a tabular format; and
storing the information of the plurality of virtual connections in a separate connection port mapping file configured to be used as a reference during network deployment.
